(19) United States
(12) Patent Application Publication
(10) Pub. No.: US 2012/0241199 A1
(43) Pub. Date: Sep. 27, 2012

(54) CONDUCTIVE SUBSTRATE, METHOD OF MANUFACTURING THE SAME AND TOUCH PANEL

(76) Inventors: Hiroshi Kobayashi, Tokyo (JP); Noritoshi Tomikawa, Tokyo (JP)

(21) Appl. No.: 13/490,112

(22) Filed: Jun. 6, 2012

Related U.S. Application Data
(63) Continuation of application No. PCT/JP2010/053917, filed on Mar. 9, 2010.

(30) Foreign Application Priority Data
Dec. 10, 2009 (JP) 2009-280201

(51) Int. Cl. H05K 1/00; H05K 3/46; H05K 3/10; B32B 15/00

(52) U.S. Cl. 174/250; 428/457; 427/97.1; 427/97.3

(57) ABSTRACT

One embodiment of the present invention is a conductive substrate including: a conductive layer, and a transparent conductive layer on at least one surface of a transparent substrate in this order from the transparent substrate side. According to the present invention, it becomes possible to provide a conductive substrate, wherein positioning of the transparent conductive layer and the metal wiring is easy, a method of manufacturing thereof, and a touch panel, even in the conductive substrate where the shape of the transparent conductive layer pattern is inconspicuous.

This application is a continuation of International Application No. PCT/JP2010/053917, filed on Mar. 9, 2010, the entire contents of which are incorporated herein by reference.

### BACKGROUND OF THE INVENTION

1. Field of the Invention

The present invention relates to a conductive substrate used in a touch panel which is attached as an input device, and a method of manufacturing the conductive substrate.

2. Background Art

In recent years, transparent touch panels have been attached as input devices to the display of various electronic devices. Examples of touch panel systems include a resistive type and a capacitive type. Particularly, multi-touch is possible with the capacitive type, and is often employed in mobile devices and the like.

The capacitive type touch panel is configured so as to be capable of detecting a change in voltage between a front surface transparent conductive film and a rear surface transparent conductive film, where a transparent conductive film on which X coordinate and Y coordinate patterns are respectively formed on the front surface and the rear surface of a substrate, is connected to a circuit via a metal wiring pattern. As a method of forming a transparent conductive film pattern, there is a method using photolithography as in JP-A-1-197911, JP-A-2-109205 and JP-A-2-309510. As another method, as in JP-A-9-142884, there is a method of performing pattern exposure using an indium compound having a functional group or a moiety which reacts to light, and using a tin compound having a similar functional group or moiety as a composition for forming a conductive film. There is also a method of performing pattern forming using laser light, as in JP-A-2008-140130. Furthermore, there is a case where the metal wiring pattern is formed at the same time as the transparent conductive film pattern, as in JP-A-1-197911, and a case where the metal wiring pattern is formed by printing or the like on a transparent conductive film using a metal film of Ag ink, Al, or the like, as in JP-A-2008-140130 or JP-A-2008-33777.

### SUMMARY OF THE INVENTION

However, according to the method using photolithography as in JP-A-1-197911, JP-A-2-109205 and JP-A-2-309510, after forming a transparent conductive film pattern, when printing a metal wiring pattern as in JP-A-2008-140130 or JP-A-2008-33777, when adopting a fine configuration in order to make the pattern shape of the transparent conductive film pattern inconspicuous, there is a problem that a positioning marker, which is for fitting the metal wiring pattern into the transparent conductive film pattern, cannot be read, and the transparent conductive film pattern and the metal wiring pattern deviate from each other. Meanwhile, in JP-A-1-197911, forming the metal wiring pattern at the same time as the transparent conductive film pattern is disclosed, but there are problems in that ITO, which is used for the transparent conductive film, is included in the metal wiring pattern, and that a large amount of indium, which is a scarce resource, must be used.

The present invention is made in consideration of the problems of the related art, and an object thereof is to reevaluate the manufacturing process, and provide a conductive substrate where positional accuracy of the transparent conductive film pattern shape and the metal wiring pattern is high, a method of manufacturing thereof, and a touch panel, even in a conductive substrate where the shape of the transparent conductive film pattern is inconspicuous.

According to the present invention, it becomes possible to provide a conductive substrate, wherein positioning of the transparent conductive film and the metal wiring is easy, a method of manufacturing thereof, and a touch panel, even in the conductive substrate where the shape of the transparent conductive film pattern is inconspicuous.

A first aspect of the present invention is a conductive substrate including: a transparent substrate; a conductive layer on at least one surface of the transparent substrate; and a transparent conductive layer on the conductive layer.

A second aspect of the present invention is a method of manufacturing a conductive substrate including: forming a conductive layer on at least one surface of a transparent substrate; and followed by forming a transparent conductive layer on a front surface of the conductive layer.

### BRIEF DESCRIPTION OF THE DRAWINGS

FIG. 1 is an explanatory diagram of cross-section example 1 of the conductive substrate of the present invention;

FIG. 2 is an explanatory diagram of cross-section example 2 of the conductive substrate of the present invention;

FIG. 3 is an explanatory diagram of cross-section example 3 of the conductive substrate of the present invention;

FIG. 4 is an explanatory diagram of cross-section example 4 of the conductive substrate of the present invention;

FIG. 5 is an explanatory diagram of cross-section example 5 of the conductive substrate of the present invention;

FIG. 6 is an explanatory diagram of cross-section example 6 of the conductive substrate of the present invention;

FIG. 7 is an explanatory diagram of cross-section example 7 of the conductive substrate of the present invention;

FIG. 8 is an explanatory diagram of cross-section example 8 of the conductive substrate of the present invention;

FIG. 9 is an explanatory diagram of cross-section example 9 of the conductive substrate of the present invention;

FIG. 10 is an explanatory diagram of cross-section example 10 of the conductive substrate of the present invention;

FIG. 11 is an explanatory diagram of the transparent conductive film pattern example (X coordinate);

FIG. 12 is an explanatory diagram of the transparent conductive film pattern example (Y coordinate);

FIG. 13 is an explanatory diagram of the positional relationship between the X coordinate and the Y coordinate of the transparent conductive film pattern example; and

FIGS. 14A to 14I are explanatory diagrams of the conductive substrate pattern forming process example of the present invention.

### DESCRIPTION OF PREFERRED EMBODIMENTS

Hereafter, description will be given of embodiments for realizing the present invention using the drawings. (In this specification, a word of a film may be used instead of a layer) Here, the present invention is not limited to the embodiments disclosed below, and such changes as modifications to the design and the like, based on the knowledge of a person skilled in the art, may be added, and embodiments wherein such changes are added are also included in the scope of the present invention.

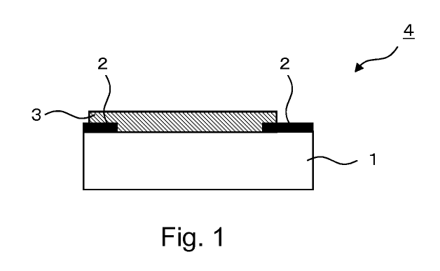

FIG. 1 is an explanatory diagram of cross-section example 1 of the conductive substrate of the present invention. Conductive substrate 4 is configured by a conductive layer 2 provided on one surface of transparent substrate 1, and a transparent conductive film 3 which does not have a pattern. Since the transparent conductive film 3 does not have a pattern, the conductive substrate 4 of FIG. 1 may be used as a conductive substrate of a resistive film type touch panel.

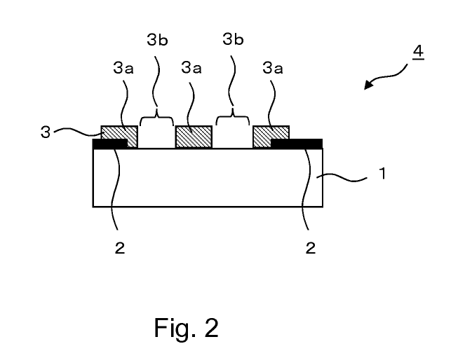

FIG. 2 is an explanatory diagram of cross-section example 2 of the conductive substrate of the present invention. Conductive substrate 4 is configured by a conductive layer 2 provided on one surface of transparent substrate 1, and a transparent conductive film 3 on which a conductive pattern region 3a and a non-conductive pattern region 3b are formed. Since the transparent conductive film 3 has a pattern, the conductive substrate 4 of FIG. 2 may be used as a conductive substrate of an electrostatic capacitance type touch panel. Here, the conductive pattern region refers to a portion among the transparent conductive layers which has conductivity, and a non-conductive pattern region refers to a portion among the transparent conductive layers excluding the portion which has conductivity, which is a portion that does not have conductivity.

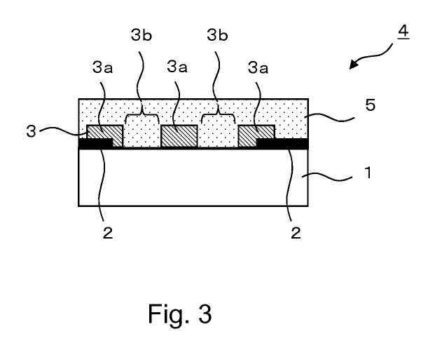

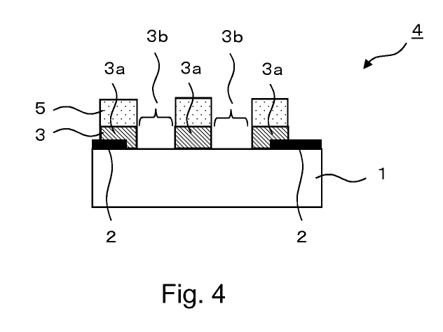

As a conductive substrate of the electrostatic capacitance type touch panel of the present invention, the conductive substrates of FIG. 3 to FIG. 10, as well as of FIG. 2, may be exemplified. FIG. 3 and FIG. 4 are explanatory diagrams of cross-section examples 3 and 4 of the conductive substrate of the present invention. As in FIG. 3, an optical adjustment layer 5 may be provided on the transparent conductive film 3 shown in FIG. 2. Furthermore, as in FIG. 4, in some configurations the optical adjustment layer 5 may be only provided on the conductive pattern region 3a of the transparent conductive film 3.

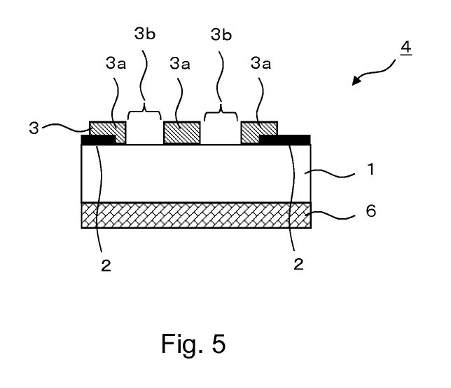

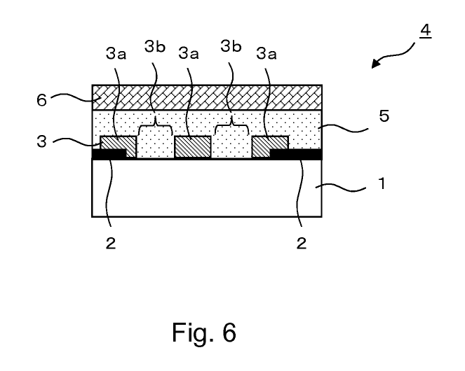

FIG. 5 and FIG. 6 are explanatory diagrams of cross-section examples 5 and 6 of the conductive substrate of the present invention. As in FIG. 5, the surface hardness is increased, and the substrate becomes difficult to scratch due to forming a hard coat layer 6 on at least one of the surfaces of the conductive substrate 4 shown in FIG. 2. Here, an example is shown where a hard coat layer 6 is formed on a surface opposite to the side where the conductive layer 2 is formed. However, it is possible to appropriately select among forming the hard coat layer 6 between the conductive layer 2 and the transparent substrate 1, forming it on the surface of the transparent conductive film 3 on which a conductive pattern region 3a and a non-conductive pattern region 3b are formed, as in FIG. 6, forming it on the front surface of the optical adjustment layer 5, and the like.

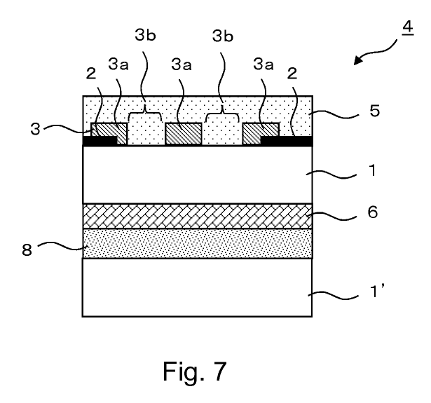

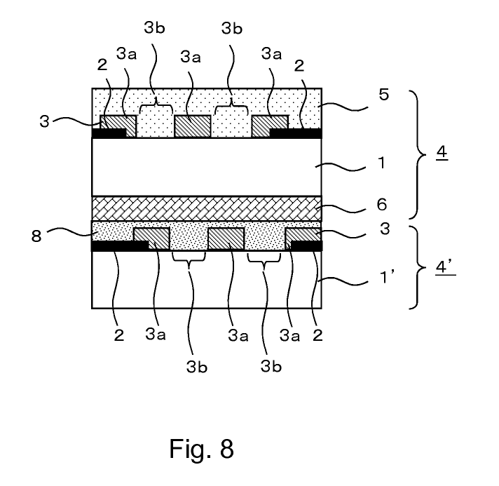

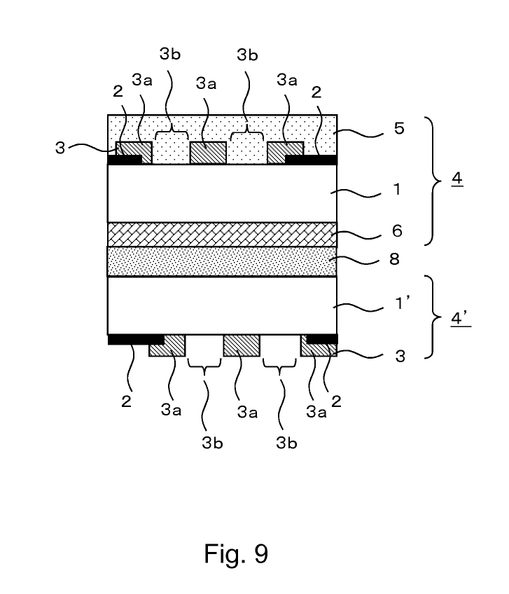

FIGS. 7 to 9 are respectively explanatory diagrams of cross-section examples 7 to 9 of the conductive laminated body of the present invention. Another transparent substrate 1′ is bonded onto the hard coat layer 6 side of the conductive substrate 4 shown in FIG. 5 via an adhesive layer 8. Here, the bonded other transparent substrate 1′ may configure another conductive substrate 4′ with the same configuration as the conductive substrate 4 shown in FIG. 2. Specifically, as in FIG. 8, using the other conductive substrate 4′ on which a conductive layer 2 and a transparent conductive film 3 on which a conductive pattern region 3a and a non-conductive pattern region 3b are formed are provided on one surface of the other transparent substrate 1′, the surface of the transparent conductive film 3 of the other conductive substrate 4′ and the hard coat layer 6 of the conductive substrate 4 are bonded together via an adhesive layer 8. Furthermore, as in FIG. 9, the other transparent substrate 1′ of the other conductive substrate 4′ and the transparent substrate 1 of the conductive substrate 4 may be bonded together via the adhesive layer 8. In the case of FIG. 8 or FIG. 9, it is preferable for the transparent conductive film 3 pattern of the conductive substrate 4 and the transparent conductive film 3 pattern of the other conductive substrate 4′ to be mutually orthogonal patterns, as described below.

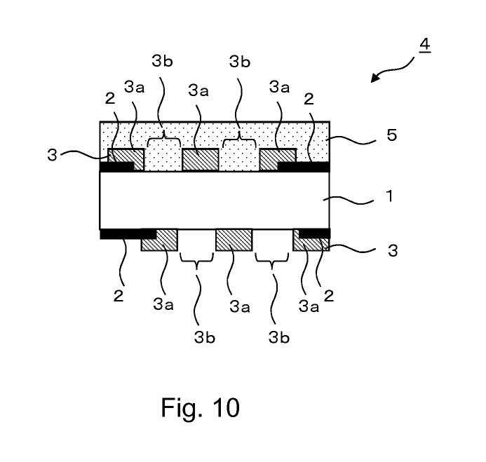

FIG. 10 is an explanatory diagram of cross-section example 10 of the conductive laminated body of the present invention. A transparent conductive film pattern, which is orthogonal to the transparent conductive film 3 pattern on the surface opposite to the surface provided with the transparent conductive film 3 of the transparent substrate 1 of the conductive substrate 4 shown in FIG. 3, may be provided. In the case of the opposite surface, it is also preferable to carry out the configuration in the order of the transparent substrate 1, the conductive layer 2, and the transparent conductive film on which the conductive pattern region 3a and the non-conductive pattern region 3b are formed.

Next, the components of the conductive substrate 4 of the present invention will be described in detail. Here, the other conductive substrate 4′ will be treated as equivalent to the conductive substrate 4.

Examples of the shapes of the transparent substrate 1 used in the present invention include a plate shape, a film shape or the like. In addition to glass, high polymer resin may be used as a material of the transparent substrate 1. The high polymer resin is not particularly limited, as long as the high polymer resin has sufficient strength in the film forming process and the post-processing, and has good front surface smoothness, and for example, examples include polyethylene terephthalate, polybutylene terephthalate, polyethylene naphthalate, polycarbonate, polyether sulfone, polysulfone, polyarylate, cyclic polyolefin, polyimide, or the like. A thickness of approximately 10 μm to 200 μm is used as the thickness of the high polymer resin, taking thinning of the member, and flexibility of the substrate into consideration.

As materials included in the transparent substrate 1, as well as the materials above, various well-known additives or stabilizers such as, for example, an antistatic agent, an ultraviolet inhibitor, a plasticizer, a lubricant, an easy adhesive, and the like may be used on the front surface of the substrate. In order to improve adhesion to the thin film, corona processing, low temperature plasma processing, ion bombardment processing, chemical treatment, or the like may be administered as preprocessing.

Here, the other transparent substrate 1′ will be treated as equivalent to the transparent substrate 1.

The conductive layer 2 used in the present invention is a metal wiring pattern connected to a circuit which can detect a change in voltage, and is formed so as to come into contact with the conductive pattern region 3a of the transparent conductive film 3. Since the conductive pattern region 3a of the transparent conductive film 3 is transparent, and is often a fine pattern for accurately reading positional information, there is a necessity for the conductive layer 2 to be formed by accurately performing positioning with the conductive pattern region 3a of the transparent conductive film 3.

Examples of the conductive layer 2 include a metal film patterned by a method using photolithography or a laser; silver ink, carbon nanotubes (CNT), conductive resins, or the like, which are pattern formed by screen printing or ink jet printing, however as long as the material can be formed into a thin line of approximately 100 μm or less and obtain sufficient conductivity even when thinned, any method may be used as long as the method is a forming technology. Furthermore, in the patterns of metal film, silver ink, CNT or conductive resin, or the like, the conductive layer 2 may be formed by combining other materials.

It is preferable to provide the conductive layer 2 in the order of, from the transparent substrate 1 side, the conductive layer 2 and the transparent conductive film 3. By providing the transparent conductive film 3 after providing the conductive layer 2, it is possible to easily perform positioning between the conductive layer 2 and the transparent conductive film 3. Conversely, when provided in the order of, from the transparent substrate 1 side, the transparent conductive film 3 and the conductive layer 2, since the pattern of transparent conductive film 3 is a transparent and fine configuration, it is difficult to accurately align the conductive layer 3 with the position of the transparent conductive film 3 pattern, which is not preferable.

Furthermore, by forming a positioning marker as well as the conductive layer 2, position adjustment with the transparent conductive film pattern becomes easier. Depending on the material, heat or ultraviolet radiation may be appropriately used for drying and curing.

It is preferable that the sheet resistance of the conductive layer 2 has a conductivity of 1 Ω/sq or less. By using this range, sufficient conductivity may be obtained even if the lines are thinned. Here, the sheet resistance may be measured using the four terminal sensing method, or calculated from the pattern shape and the resistance value thereof.

The hard coat layer 6 used in the present invention is provided in order to give mechanical strength to the conductive substrate 4. The resin used is not particularly restricted, but a resin with transparency, appropriate hardness and mechanical strength is preferable. Specifically, photocurable resins such as monomers or cross linked oligomers of which the main component is an acrylate with 3 functional groups or more in which 3D cross linkage is anticipated, are preferable.

As acrylate monomers with 3 functional groups or more, trimethylolpropane triacrylate, EO-modified isocyanuric acid triacrylate, pentaerythritol triacrylate, dipentaerythritol triacrylate, dipentaerythritol tetraacrylate, dipentaerythritol pentaacrylate, dipentaerythritol hexaacrylate, ditrimethylolpropane tetraacrylate, pentaerythritol tetraacrylate, polyester acrylate, and the like are preferable. EO-modified isocyanuric acid triacrylate and polyester acrylate are particularly preferable. These may be used alone, or 2 types or more may also be used together. Furthermore, so-called acrylic resins such as epoxy acrylate, urethane acrylate, polyol acrylate, and the like may be used together, as well as these acrylates with 3 functional groups or more.

As cross linked oligomers, acrylate oligomers such as polyester (meth)acrylate, polyether (meth)acrylate, polyurethane (meth)acrylate, epoxy (meth)acrylate, silicone (meth)acrylate, and the like are preferable. Specifically, there are polyethylene glycol di (meth)acrylate, polypropylene glycol di(meth)acrylate, epoxy acrylate of bisphenol A, polyurethane diacrylate, cresol novolak type epoxy (meth)acrylate, and the like.

The hard coat layer 6 may include other particles and additives of photopolymerization initiators or the like.

Examples of additional particles include organic or inorganic particles, however, taking transparency into consideration, it is preferable to use organic particles. Examples of organic particles include particles formed of acrylic resin, polystyrene resin, polyester resin, polyolefin resin, polyamide resin, polycarbonate resin, polyurethane resin, silicone resin and fluorine resin, and the like.

The average particle diameter of the particles varies depending on the thickness of the hard coat layer 6, but due to reasons of external appearance such as haze or the like, a lower limit of 2 μm or more, more preferably of 5 μm or more, and an upper limit of 30 μm or less, preferably 15 μm or less is used. Furthermore, for the same reason, the content of particles in relation to resin is preferably from 0.5 wt % to 5 wt %.

When adding a photopolymerization initiator, as a radical generating type photopolymerization initiator, there are benzoins such as, benzoin, benzoin methyl ether, benzoin ethyl ether, benzoin isopropyl ether, benzyl methyl ketal, or the like, and alkyl ethers thereof, and acetophenones such as, acetophenone, 2,2-dimethoxy-2-phenylacetophenone, 1-hydroxycyclohexyl phenyl ketone, or the like, and anthraquinones such as, methyl anthraquinone, 2-ethyl anthraquinone, 2-amyl anthraquinone, or the like, and thioxanthones such as, thioxanthone, 2,4-diethyl thioxanthone, 2,4-diisopropyl thioxanthone, or the like, and ketals such as, acetophenone dimethyl ketal, benzyl dimethyl ketal, or the like, and benzophenones such as, benzophenone, 4,4-bis-aminomethyl benzophenone, or the like, and azo compounds. These may be used alone or as a compound of 2 types or more, furthermore, auxiliary photo initiators or the like of tertiary amines such as triethanolamine, methyl diethanolamine or the like, or benzoic acids such as 2-dimethylamino ethyl benzoate, ethyl 4-dimethylaminobenzoate, or the like, may be combined and used.

The amount of the above photopolymerization initiator to add in relation to the main component, resin, is from 0.1 wt % to 5 wt %, and preferably from 0.5 wt % to 3 wt %. Below the lower limit value, the curing of the hard coat layer becomes insufficient, and is not preferable. Furthermore, when exceeding the upper limit value, yellowing of the hard coat layer occurs or weather resistance is reduced, therefore this is not preferable. The light used for curing the photocurable resin is ultraviolet rays, an electron beam, or gamma rays or the like, and in the case of an electron beam or gamma rays, it is not always necessary to include a photopolymerization initiator or an auxiliary photo initiator. As a radiation source, a high pressure mercury vapor lamp, a xenon lamp, a metal halide lamp or accelerated electrons may be used.

Furthermore, the thickness of the hard coat layer 6 is not particularly limited, but a range from 0.5 μm to 15 μm is preferable. Furthermore, it is more preferable that the refractive index be equal to or similar to the transparent substrate 1, and preferably approximately from 1.45 to 1.75.

The method of forming the hard coat layer 6 is to dissolve a material, which absorbs the main component resin and ultraviolet rays, in a solvent, and form the hard coat layer 6 using a well-known coating method such as a die coater, a curtain flow coater, a roll coater, a reverse roll coater, a gravure coater, a knife coater, a bar coater, a spin coater, a micro gravure coater, or the like.

The solvent is not particularly limited, as long as the solvent dissolves the above main component resin. Specifically, examples of the solvents are ethanol, isopropyl alcohol, isobutyl alcohol, benzene, toluene, xylene, acetone, methyl ethyl ketone, methyl isobutyl ketone, ethyl acetate, n-butyl acetate, isoamyl acetate, ethyl lactate, methyl cellosolve, ethyl cellosolve, butyl cellosolve, methyl cellosolve acetate, propylene glycol monomethyl ether acetate, or the like. One type of these solvents may be used alone, or 2 or more types may be used together.

An optical adjustment layer 5 is a layer which has a function of making a pattern formed on the transparent conductive film 3 inconspicuous, and is for improving visibility. When using an inorganic compound, materials such as oxides, sulfides, fluorides, nitrides, or the like may be used. It is possible to adjust the optical characteristics of the thin film, which has a different refractive index due to the materials thereof, formed of the above inorganic compound, by forming the thin film which has a different refractive index at a specific film thickness. Furthermore, as the number of the optical function layers, there may be a plurality of layers corresponding to the desired optical characteristics.

Examples of materials with a low refractive index include magnesium oxide (1.6), silicon dioxide (1.5), magnesium fluoride (1.4), calcium fluoride (1.3 to 1.4), cerium fluoride (1.6), aluminum fluoride (1.3), or the like. Furthermore, with a high refractive index, titanium oxide (2.4), zirconium oxide (2.4), zinc sulfide (2.3), tantalum oxide (2.1), zinc oxide (2.1), indium oxide (2.0), niobium oxide (2.3), and tantalum oxide (2.2) may be exemplified. Herein, the numerical values within brackets above represent the refractive index.

Meanwhile, as the optical adjustment layer 5, a resin the same as the hard coat layer 6 may be used. In this case, the refractive index of the resin may be increased by dispersing high refractive index inorganic fine particles of zirconium oxide, titanium oxide, or the like in the resin.

As the transparent conductive film 3, any one of indium oxide, zinc oxide, and tin oxide, or a compound of 2 types or 3 types thereof, and in addition, a material with other additives added thereto may be exemplified. The material is not particularly limited, and various materials can be used in accordance with the objective and the purpose thereof. At present, the most reliable and field-tested material is indium tin oxide (ITO).

When using indium tin oxide (ITO) as the transparent conductive film 3, which is the most general transparent conductive material, the content ratio of tin oxide doped with indium oxide is an arbitrarily selected ratio, corresponding to the desired design of the device. For example, when the base material is a plastic film, the sputtering target material, used in order to crystallize the thin film with the aim of increasing mechanical strength, preferably has a tin oxide content ratio of below 10 wt %, and in order to make the thin film amorphous and flexible, it is preferable for the content ratio of tin oxide to be 10 wt % or more. Furthermore, when low resistance is desired in the thin film, it is preferable for the content ratio of tin oxide to be in a range from 3 wt % to 20 wt %.

It is preferable for the sheet resistance of the transparent conductive film 3 to have a conductivity of from 100 Ω/sq to 700 kΩ/sq. By using this range, excellent durability and transparency are obtained, and it becomes possible to accurately detect the contact position. Furthermore, similarly to the conductive layer 2, the sheet resistance may be measured using the four terminal sensing method or calculated from the pattern shape and the resistance value thereof.

When using an inorganic compound for the optical adjustment layer 5, and as the method of manufacturing the transparent conductive film 3, any film forming method capable of controlling the film thickness may be used, and among the methods of film forming, a dry method is superior for forming a thin film. For this, a vacuum deposition method, a physical vapor phase deposition method such as sputtering or the like, and a chemical vapor phase deposition method such as a CVD method may be used. Particularly, in order to form a uniform large area thin film, it is preferable to adopt a sputtering method in which the process is stable and the thin film is refined.

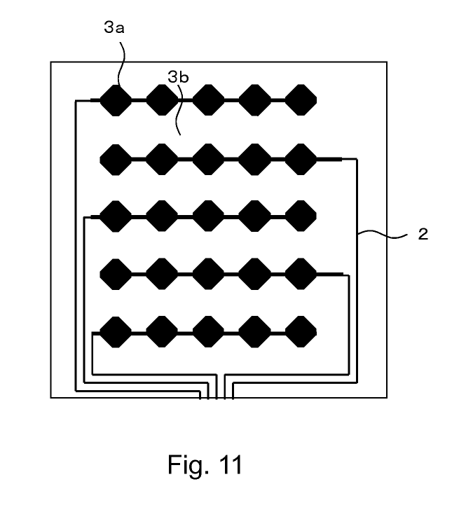

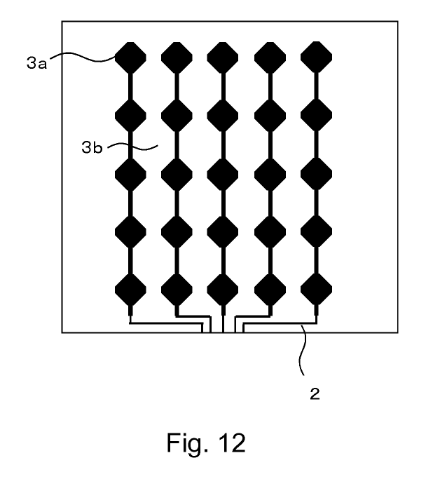

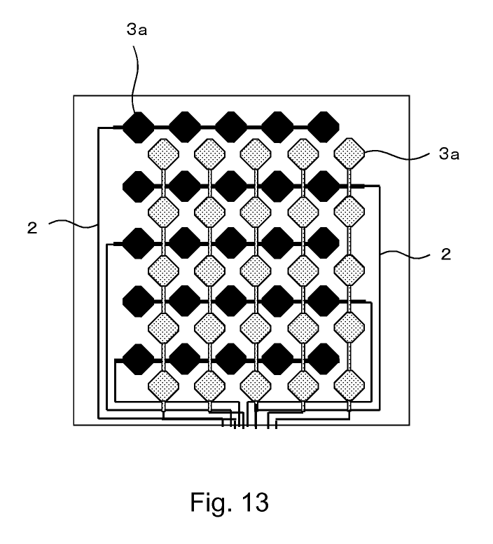

The transparent conductive film 3 is patterned as in FIG. 11 or FIG. 12. The pattern formed as in FIG. 11 or FIG. 12 is formed of the conductive pattern region 3a, which is represented by black, and the non-conductive pattern region 3b, which is represented by white. The conductive pattern region 3a contacts with the conductive layer 2, and is connected to a circuit which can detect changes in voltage. When a person's finger or the like approaches the conductive pattern region 3a which is a detection electrode, the overall electrostatic capacitance changes, causing the voltage of the circuit to fluctuate, and the contact position may be determined. The patterns of FIG. 11 or FIG. 12 are bonded together, are combined so as to be mutually orthogonal as in FIGS. 13, and 2 dimensional positional information may be obtained by connecting to a voltage change detection circuit.

Furthermore, the transparent conductive film 3 preferably has a difference of total light transmittance of 1% or less between the conductive pattern region 3a and the non-conductive pattern region 3b of the transparent conductive film 3, and when within this range, the pattern shape becomes inconspicuous even if different patterns are formed on each side of the conductive substrate, and visibility is improved. Furthermore, it is preferable for the transmissive hue b* difference to be 1.5 or less between the conductive pattern region and the non-conductive pattern region. When within this range, the pattern shape becomes more inconspicuous, and visibility is further improved.

In the transparent conductive film 3 pattern shapes, there are mesh type patterns, or the like, as well as diamond type patterns as in FIG. 11 or FIG. 12, and in order to accurately read the 2 dimensional positional information, it is necessary to form the pattern so as to be as fine as possible, and to perform positioning of the 2 patterns accurately.

As a method of forming the transparent conductive film 3 pattern, examples include a method using photolithography in which a resist is applied onto the transparent conductive film 3, and after forming the pattern by exposing and developing, the transparent conductive film is chemically dissolved; a method of vaporizing using a chemical reaction in a vacuum; and a method in which the transparent conductive film is sublimed using a laser. The pattern forming method may be appropriately selected in accordance with pattern shape, accuracy, or the like, however, taking pattern accuracy and thinning into consideration, a method using photolithography is preferable.

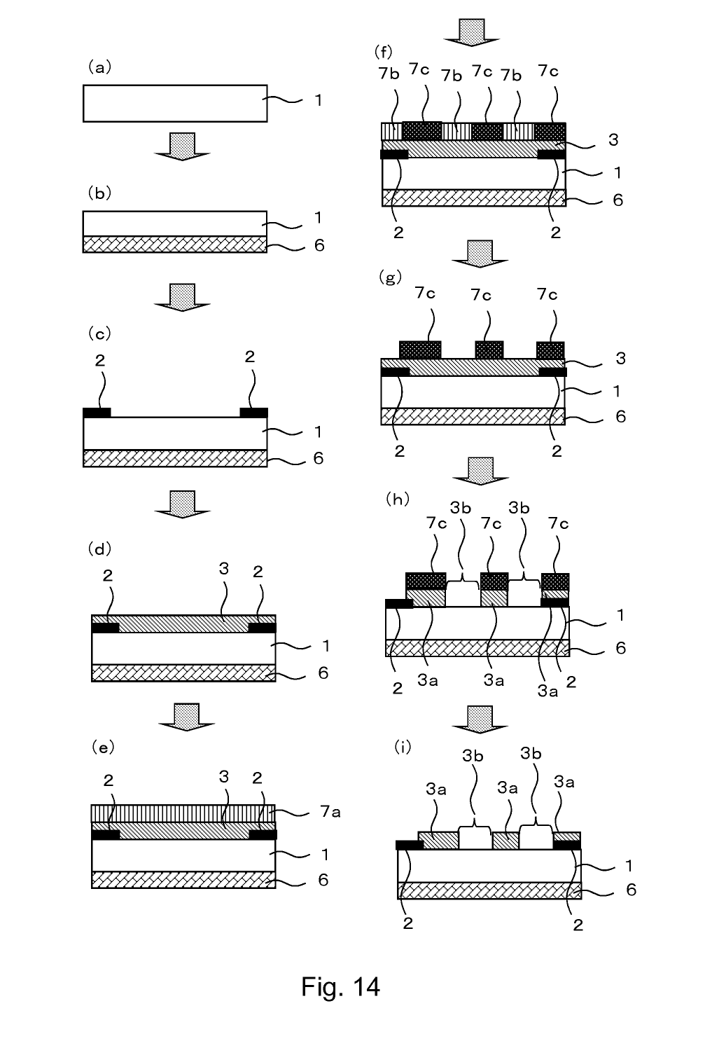

The conductive substrate 4 pattern forming process of the invention will be shown in FIGS. 14A to 14I, using the conductive substrate 4 shown in FIG. 5 as an example. Firstly, the transparent substrate 1 is prepared (process (a), FIG. 14A), then the hard coat layer 6 is formed on one surface (process (b), FIG. 14B). The conductive layer 2 is formed in a predetermined position on the surface opposite to the hard coat layer 6 of the transparent substrate 1 (process (c), FIG. 14C). Furthermore, the transparent conductive film 3 is film formed (process (d), FIG. 14D). Subsequently, the resist 7a is applied to the front surface of the conductive layer 2 and the transparent conductive film 3 (process (e), FIG. 14E), the light source for forming the pattern, the pattern mask represented by FIG. 11 or FIG. 12, and the transparent substrate coated with the resist 7a are arranged in order on the transparent conductive film 3, and the transparent conductive film 3 is exposed to the light of the light source to create the regions of the resist 7b and 7c (process (f), FIG. 14F). Here, the 7c is a resist which has been exposed to light. Subsequently, the resist 7b which has not been exposed to light is removed by developing solution (process (g), FIG. 14G), and the exposed portion of the transparent conductive film 3 is etched (process (h), FIG. 14H). Finally, the resist 7c exposed to light is detached, and the conductive substrate 4 is obtained (process (i), FIG. 14I).

The method of manufacture of the conductive substrate 4 of the present invention preferably has a process of forming the conductive layer 2 (c), and a process of film forming the transparent conductive film 3 (d) provided in this order. Firstly, the conductive layer 2 is formed, then, by film forming the transparent conductive film 3 and forming the pattern, the transparent conductive film 3 pattern may be formed based on the position of the conductive layer 2, therefore positioning may be easily performed. Conversely, when forming the conductive layer 2 after film forming the transparent conductive film 3 and forming the pattern, the conductive layer 2 must be formed so as to conform to the position of the transparent conductive film 3 pattern, which is transparent and has a fine shape, positioning may not be easily performed. Furthermore, when forming the conductive layer 2 after film forming the transparent conductive film 3 and forming the pattern, since the silver ink which forms the conductive layer 2 is dried at a high temperature, the sheet resistance value of the transparent conductive film 3, which has already been film formed, increases, and the contact position can no longer be accurately detected.

In the process of forming the conductive layer 2 (c), it is preferable to form the positioning marker at the same time as forming the conductive layer 2. In this manner, when the transparent conductive film 3 pattern is subsequently formed, the pattern may be formed using the positioning marker as a guide.

FIGS. 14A to 14I show each process of a method of forming the pattern using a negative type resist, however, the pattern may also be formed using a positive type resist.

The conductive substrate 4 of the present invention shown in the other figures may also similarly form the conductive pattern region 3a and the non-conductive pattern region 3b of the transparent conductive film 3 by the above processes.

The method of manufacture of the conductive substrate 4 of the present invention may include a process of pasting the other transparent substrate 1′ onto the transparent substrate 1 of the conductive substrate 4 which has been obtained via the process shown in FIGS. 14A to 14I. Furthermore, a process may be included which pastes the front surface of the transparent conductive film 3 of the other conductive substrate 4′, and the hard coat layer 6 of the conductive substrate 4 together via the adhesive layer 8, using the conductive substrate 4′ obtained via another process.

In the method of manufacture of the conductive substrate 4 of the present invention, it is preferable to perform a process of forming the conductive layer 2, a process of forming the transparent conductive film 3 or a process of forming the transparent conductive film 3 having the conductive pattern region 3a and the non-conductive pattern region 3b, a process of forming the optical adjustment layer 5, and a process of forming the hard coat layer 6, respectively by a roll-to-roll system. In this manner, the conductive substrate 4 may be efficiently mass produced. Particularly, it is preferable to perform each process in succession by a roll-to-roll system.

Next, the embodiments and the comparative examples will be explained.

### First Embodiment

Using a polyethylene terephthalate film (manufactured by TORAY INDUSTRIES, INC, thickness: 100 μm) as a transparent substrate, a coating liquid for forming a resin layer of the composition below is coated onto one of the surfaces using a micro gravure coater, is dried for 1 minute at 60° C., and is cured by ultraviolet radiation, therefore forming the hard coat layer.

### Composition of Coating Liquid for Forming a Resin Layer

Resin: SHIKOH UV-7605B (manufactured by Nippon Synthetic Chemical Industry Co., Ltd.) 100 parts by weight

Initiator: Irgacure 184 (manufactured by BASF Japan Ltd.) 4 parts by weight

Solvent: methyl acetate 100 parts by weight

On the surface opposite to the hard coat layer of the transparent substrate, the conductive layer and the positioning marker were formed by a screen printer using silver ink and dried for 30 minutes at 150° C. Subsequently, after an ITO film was film formed on the conductive layer at 25 nm using sputtering as the transparent conductive film, the transparent conductive layer pattern was formed using photolithography, based on the positioning marker of the silver ink.

In the case of the first embodiment, it was possible to form a transparent conductive film with few scratches by coating the transparent conductive film with a hard coat. Furthermore, since positioning was easy, there were no defects caused by pattern deviation. The value of the ITO film sheet resistance was stable at 200 Ω/sq.

### Second Embodiment

Using a polyethylene terephthalate film (manufactured by TORAY INDUSTRIES, INC, thickness: 100 μm) as a transparent substrate, a hard coat layer the same as the first embodiment was formed on one of the surfaces, and a conductive layer and a positioning marker the same as the first embodiment were formed on the surface opposite to the hard coat layer of the transparent substrate. Subsequently, after film forming an ITO film of 25 nm the same as the first embodiment, and after SiO₂ was film formed at 70 nm as an optical adjustment layer, the SiO₂ and the ITO were etched to the same pattern using photolithography based on the silver ink positioning marker, and a conductive substrate was obtained.

In the case of the second embodiment, it was possible to form a transparent conductive film with few scratches by coating the transparent conductive film with a hard coat. Furthermore, since positioning was easy, there were no defects caused by pattern deviation. The value of the ITO film sheet resistance was stable at 200 Ω/sq, and also, in relation to the optical characteristics, the difference of total light transmittance between the conductive pattern region and the non-conductive pattern region was 0.3%, and a conductive substrate where it is difficult to visually recognize the pattern was obtained.

### Comparative Example

Using a polyethylene terephthalate film (manufactured by TORAY INDUSTRIES, INC, thickness: 100 μm) as a transparent substrate, a hard coat layer the same as the first embodiment was formed on one of the surfaces, and, as an optical adjustment layer, 10 nm of TiO₂ and 56 nm of SiO₂, and as a transparent conductive film, 25 nm of an ITO film were respectively film formed on the surface opposite to the hard coat layer of the transparent substrate, using a sputtering method. Subsequently, a conductive pattern region, a non-conductive pattern region, and a positioning marker were formed on the ITO film using photolithography, and finally, a conductive layer was formed by a screen printer using silver ink, dried for 30 minutes at 150° C., and a conductive substrate was obtained.

In the case of the comparative example, the difference of total light transmittance between the conductive pattern region and the non-conductive pattern region was 0.7%, and a conductive substrate where it is difficult to visually recognize the pattern was obtained, however, the positioning marker was not readable in the screen printing process where a conductive layer was provided, and many positioning defects occurred. Furthermore, the value of the ITO film sheet resistance, which was 200 Ω/sq after film forming, was confirmed to have increased to 800 Ω/sq.

What is claimed is:

1. A conductive substrate comprising:
a transparent substrate;
a conductive layer on at least one surface of the transparent substrate;
and
a transparent conductive layer on the conductive layer.

2. The conductive substrate according to claim 1,
wherein the transparent conductive layer has a conductive pattern region and a non-conductive pattern region.

3. The conductive substrate according to claim 2,
wherein one or more optical adjustment layers are formed on a front surface of the transparent conductive layer.

4. The conductive substrate according to claim 2,
wherein one or more optical adjustment layers are formed only on a front surface of the conductive pattern region of the transparent conductive layer.

5. The conductive substrate according to claim 3,
further comprising a hard coat layer which is formed between any of the conductive layer, the transparent layer, and the one or more optical adjustment layers, or is formed at a most front surface of the conductive substrate.

6. The conductive substrate according to claim 5,
wherein a sheet resistance value of the conductive layer is equal to or less than 1 Ω/sq, and the sheet resistance value of the transparent conductive layer is from 100 Ω/sq to 700 kΩ/sq.

7. A touch panel including the conductive substrate according to claim 6.

8. The conductive substrate according to claim 2,
wherein the conductive substrate is bonded to another transparent substrate or another conductive substrate via an adhesive layer.

9. The conductive substrate according to claim 8,
wherein a sheet resistance value of the conductive layer is equal to or less than 1 Ω/sq, and the sheet resistance value of the transparent conductive layer is from 100 Ω/sq to 700 kΩ/sq.

10. A touch panel including the conductive substrate according to claim 9.

11. A method of manufacturing a conductive substrate comprising:
forming a conductive layer on at least one surface of a transparent substrate; and followed by
forming a transparent conductive layer on a front surface of the conductive layer.

12. The method of manufacturing a conductive substrate according to claim 11,
wherein the forming of the transparent conductive layer on the front surface of the conductive layer includes forming the transparent conductive to have a conductive pattern region and a non-conductive pattern region on the front surface of the conductive layer.

13. The method of manufacturing a conductive substrate according to claim 12, further comprising either one or both of:
forming an optical adjustment layer and forming a hard coat layer.

14. The method of manufacturing a conductive substrate according to claim 13,
wherein all of the forming processes are performed by a roll-to-roll system.
